(19) United States
(12) Patent Application Publication
(10) Pub. No.: US 2021/0212194 A1
(43) Pub. Date: Jul. 8, 2021

(54) ELECTRONIC APPARATUS AND METHOD OF ASSEMBLING ELECTRONIC APPARATUS

(71) Applicant: Delta Electronics (Shanghai) Co., Ltd., Shanghai (CN)

(72) Inventors: Zhen ZHOU, Shanghai (CN); Peiai YOU, Shanghai (CN); Hao SUN, Shanghai (CN); Minli JIA, Shanghai (CN)

(21) Appl. No.: 17/100,965

(22) Filed: Nov. 23, 2020

(30) Foreign Application Priority Data
Jan. 2, 2020 (CN) 202010002965.X

(51) Int. Cl. H05K 1/02; H01L 23/367; B23K 1/00; H05K 3/34; H01L 23/373; H05K 1/03

(52) U.S. Cl. CPC H05K 1/0204; H01L 23/367; B23K 1/0008; B23K 2101/36; H01L 23/3735; H05K 1/0306; H05K 2201/0959; H05K 3/341

(57) ABSTRACT

An electronic apparatus includes: a circuit board having a first surface, a second surface and an opening, wherein the opening is between the first surface and the second surface; a thermal conductive material at least partially passing through the opening, and in contact with the circuit board; at least an electronic device disposed on the first surface of the circuit board, and in contact with the thermal conductive material; a heat dissipation plate disposed on the second surface of the circuit board; and an insulated thermal conductive sheet disposed between the thermal conductive material and the heat dissipation plate. By virtue of it, product volume can be reduced effectively, and a flow channel is simplified.

### CROSS-REFERENCE TO RELATED APPLICATIONS

This non-provisional application claims priority under 35 U.S.C. § 119(a) on Patent Application No. 202010002965.X filed in P.R. China on Jan. 2, 2020, the entire contents of which are hereby incorporated by reference.

Some references, if any, which may include patents, patent applications and various publications, may be cited and discussed in the description of this invention. The citation and/or discussion of such references, if any, is provided merely to clarify the description of the present invention and is not an admission that any such reference is “prior art” to the invention described herein. All references listed, cited and/or discussed in this specification are incorporated herein by reference in their entireties and to the same extent as if each reference was individually incorporated by reference.

### BACKGROUND OF THE INVENTION

### 1. Field of the Invention

The disclosure relates to an electronic apparatus, and in particular, to an electronic apparatus and a method of assembling an electronic apparatus.

### 2. Related Art

With continuously increasing of battery life of electric vehicles, a power of on-board chargers also increases. Since the current 6.6 KW power cannot satisfy customer's requirement, the requirement for developing high power three-phase chargers comes into being. Under the conditions of three-phase input, 11 KW and 22 KW are main streams of the future on-board chargers, but the volume of chargers is not increased proportionally under the pursuit of extreme charging experience in the industry, causing that a power density of the power product becomes higher, and structural design and thermal management capability of the product become one of the most important indicators reflecting and measuring performance of the on-board chargers.

In the conventional technology, the on-board chargers are mainly used with a plug-in power transistor together with an elastic clamp, which occupies a relatively large volume, resulting a large product volume. In addition, layout of components is relatively scattered, such that a flow channel of water-cooling system is complex, and water resistance is large.

Therefore, it is necessary to create an electronic apparatus and a method of assembling an electronic apparatus capable of solving disadvantages of the conventional technology.

### SUMMARY OF THE INVENTION

An object of the disclosure is to provide an electronic apparatus and a method of assembling an electronic apparatus for solving at least one disadvantage of the prior art.

Another object of the disclosure is to provide an electronic apparatus and a method of assembling an electronic apparatus, which can reduce product volume effectively and simplify a flow channel by a thermal conductive insulated material disposed between a thermal conductive material and a heat dissipation plate and cooperating with the heat dissipation plate.

To achieve the above objects, one preferable embodiment of the disclosure provides an electronic apparatus, comprising: a circuit board having a first surface, a second surface and an opening, wherein the opening is between the first surface and the second surface; a thermal conductive material at least partially passing through the opening, and in contact with the circuit board; at least one electronic device disposed on the first surface of the circuit board, and in contact with the thermal conductive material; a heat dissipation plate disposed on the second surface of the circuit board; and an insulated thermal conductive sheet disposed between the thermal conductive material and the heat dissipation plate.

To achieve the above objects, another preferable embodiment of the disclosure provides a method of assembling an electronic apparatus, comprising steps of: (a) providing a circuit board, a thermal conductive material, an electronic device, a heat dissipation plate and an insulated thermal conductive sheet; (b) soldering the circuit board and the thermal conductive material by reflow soldering; (c) soldering the circuit board and the electronic device by reflow soldering; (d) connecting the heat dissipation plate and the insulated thermal conductive sheet with a first interface material; and (e) connecting the insulated thermal conductive sheet and the thermal conductive material with a second interface material.

To be simple, by fixing a Metal-Oxide-Semiconductor Field-Effect Transistor (MOSFET) adopting a Surface Mounted Technology (SMT) and the thermal conductive material with the circuit board in a way of twice reflow soldering, cooperating with a water-cooling pipe, the disclosure at least has the following advantages:

I. The power transistor in such packaging form has a relatively small volume, and occupies a small product space;

II. There is a variety of options for the fixing form, including, for example, using an elastic clamp for fixing, or locking the circuit board by screws directly;

III. The flow channel of water-cooling system has a simple design, and small flow resistance, and good heat dissipation effect can be ensured even using a plane water channel; and

IV. A protruding part feature may be added onto the heat dissipation plate through a CNC process, so as to ensure reliable contact between the thermal conductive material and the heat dissipation plate on the circuit board with a small processing area, and achieve better heat dissipation performance.

### BRIEF DESCRIPTION OF THE DRAWINGS

FIG. 1 illustrates a structural plan view of an electronic apparatus according to one embodiment of the disclosure.

FIG. 2 illustrates a structural side view of the electronic apparatus shown in FIG. 1.

FIG. 3 illustrates a detailed structural diagram of the electronic apparatus according to one embodiment of the disclosure.

FIG. 4 illustrates a detailed structural diagram of a heat dissipation plate of the electronic apparatus according to one embodiment of the disclosure.

FIG. 5 is a diagram showing fastening manner of the electronic device according to one embodiment of the disclosure.

FIG. 6 is a diagram showing fixing manner of the electronic device according to one embodiment of the disclosure.

FIG. 7 illustrates a flow chart of a method of assembling an electronic device according to one embodiment of the disclosure.

FIG. 8 illustrates a detailed flow chart of step S200 shown in FIG. 7.

FIG. 9 illustrates a detailed flow chart of step S300 shown in FIG. 7.

FIG. 10 illustrates a detailed flow chart of step S400 shown in FIG. 7.

FIG. 11 illustrates a detailed flow chart of step S500 shown in FIG. 7.

FIG. 12 illustrates a detailed structural diagram of an electronic apparatus according to one embodiment of the disclosure.

FIG. 13 illustrates a detailed structural diagram of a heat dissipation plate of the electronic apparatus according to one embodiment of the disclosure.

### DETAILED EMBODIMENTS OF THE INVENTION

Some typical embodiments representing features and advantages of the disclosure will be described in detail in subsequent explanations. It shall be understood that the disclosure can have various variations in different embodiments without departing from the scope of the disclosure, and the description and the accompanying drawings serve to explain on the essence, not limiting the disclosure.

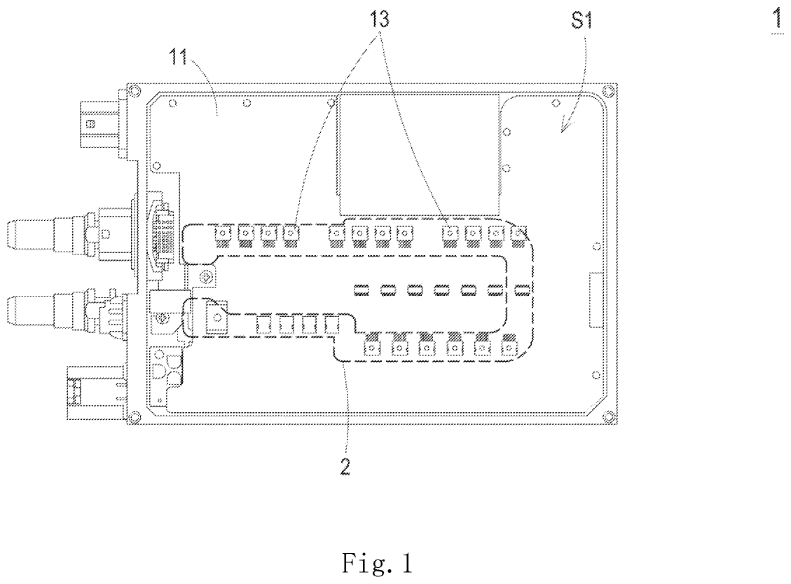

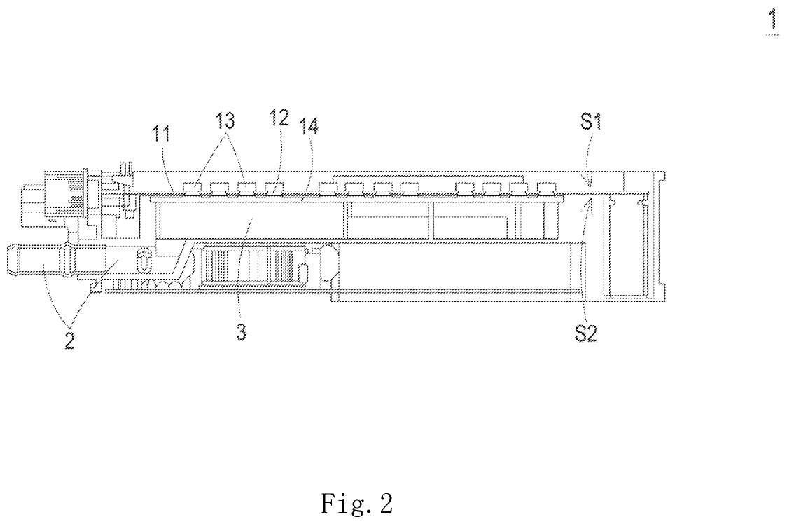

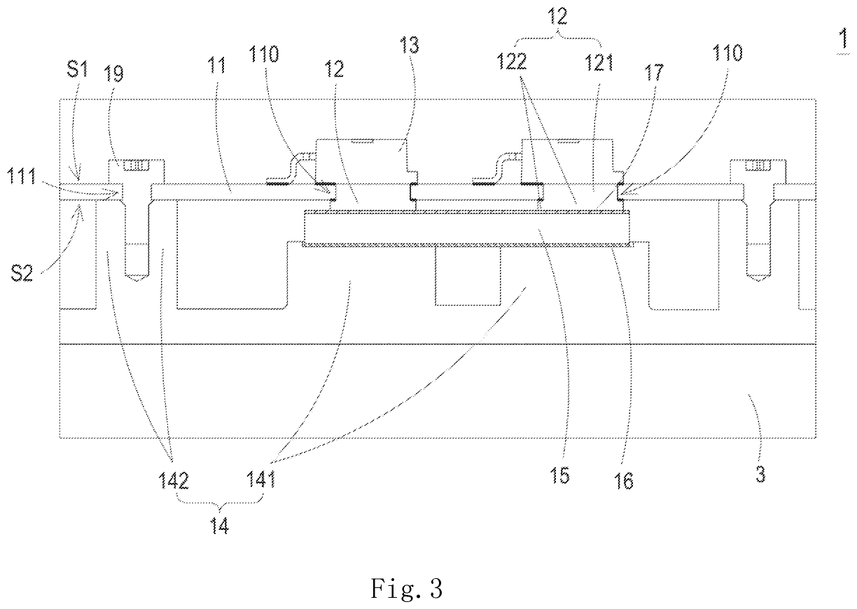

Please refer to FIGS. 1-3, wherein FIG. 1 illustrates a structural plan view of an electronic apparatus according to one embodiment of the disclosure, FIG. 2 illustrates a structural side view of the electronic apparatus shown in FIG. 1, and FIG. 3 illustrates a detailed structural diagram of the electronic apparatus according to one embodiment of the disclosure. As shown in FIGS. 1-3, according to one embodiment of the disclosure, an electronic apparatus 1 comprises a circuit board 1 having a first surface S1, a second surface S2 and an opening 110, wherein the opening 110 is between the first surface S1 and the second surface S2; a thermal conductive material 12 at least partially passing through the opening 110, and in contact with the circuit board 11; at least one electronic device 13 disposed on the first surface S1 of the circuit board 11, and in contact with the thermal conductive material 12; a heat dissipation plate 14 disposed on the second surface S2 of the circuit board 11; and an insulated thermal conductive sheet 15 disposed between the thermal conductive material 12 and the heat dissipation plate 14. By virtue of it, product volume can be reduced effectively, and a flow channel 2 is simplified.

According to the concept of the disclosure, the circuit board 11 is preferably a printed circuit board, and the opening 110 of the circuit board 11 is preferably a circular opening, but the disclosure is not limited thereto. In addition, the thermal conductive material 12 is preferably brass or red copper, and is preferably subjected to common turning processing. The electronic device 13 is preferably a power switch with Surface Mounted Technology (SMT), the heat dissipation plate 14 is preferably an aluminum alloy plate, and the insulated thermal conductive sheet 15 is preferably an aluminum oxide ceramic sheet or an aluminum nitride ceramic sheet, but the disclosure is not limited thereto. Further, when a plurality of electronic devices 13 are arranged on the circuit board 11, the arrangement manner preferably corresponds to the flow channel 2, and can cooperate with different cooling mediums 3 for heat dissipation, such as, wind- (air-) cooling or water-cooling, depending on requirement of heat dissipation, but the disclosure is not limited thereto.

Please refer to FIG. 3 again. In these embodiments, the thermal conductive material 12 has a main body part 121 passing through the opening 110 and partially projecting out of the second surface S2, and an extension part 122 extending from the main body part 121 towards both sides of the main body part 121 along a direction parallel to the circuit board 11 and in contact with the second surface S2 of the circuit board 11. In addition, the electronic apparatus 1 further comprises a first interface material 16 and a second interface material 17. The first interface material 16 is disposed between the insulated thermal conductive sheet 15 and the heat dissipation plate 14, and is preferably a liquid bond, but the disclosure is not limited thereto. The second interface material 17 is disposed between the thermal conductive material 12 and the insulated thermal conductive sheet 15, and is preferably a thermally conductive silicone grease, but the disclosure is not limited thereto. Specifically, the first interface material 16 is preferably a material having viscosity and good thermal conductivity, such as, the liquid bond, to fix and thermally conduct the heat dissipation plate 14 and the insulated thermal conductive sheet 15. The second interface material 17 is connected with the extension part 122 of the thermal conductive material 12 and the insulated thermal conductive sheet 15 to perform interface contact and filling. The second interface material 17 is preferably a material without viscosity, such as, the thermally conductive silicone grease, to facilitate future repairing, replacement and maintenance.

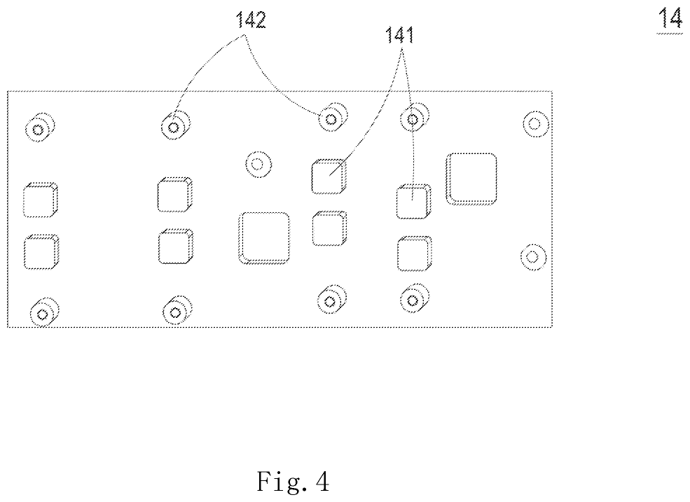

Please refer to FIG. 4 with reference to FIG. 3, wherein FIG. 4 illustrates a detailed structural diagram of a heat dissipation plate of the electronic apparatus according to one embodiment of the disclosure. As shown in FIGS. 3 and 4, the heat dissipation plate 14 of the electronic apparatus 1 of the disclosure may further have protruding parts 141. Milling processing is preferably applied to the protruding parts 141 to ensure their planarization and promote heat dissipation capability effectively. Moreover, the protruding parts 141 are formed at positions corresponding to the thermal conductive material 12. It is preferable that each of the protruding parts 141 corresponds to one electronic device 13, but the disclosure is not limited thereto. Preferably, an area of a top surface of the protruding part 141 is twice of an area of a bottom surface of the electronic device 13, and a height of the protruding part 141 is larger than or equal to 0.5 mm. In addition, the heat dissipation plate 14 can have lug bosses 142 for locking or fixing with fixing elements (such as, screws or nails).

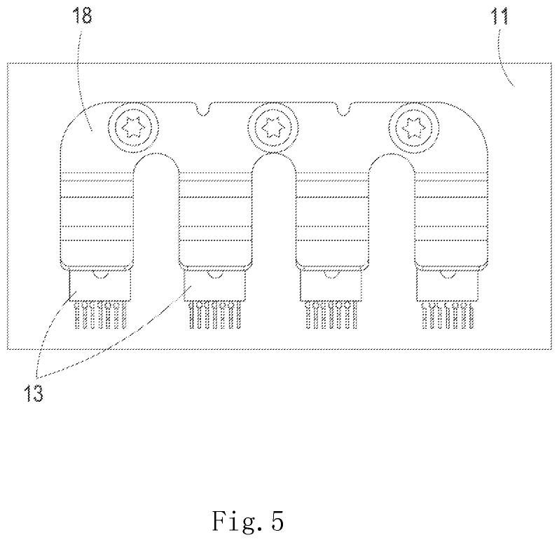

Please refer to FIG. 5 with reference to FIGS. 3 and 4, wherein FIG. 5 illustrates a diagram showing fastening manner of the electronic device according to one embodiment of the disclosure. As shown in FIGS. 3-5, the electronic device of the disclosure further comprises an elastic clamp 18 with one end locked onto the circuit board 11 and the other end pressed against the electronic device 13.

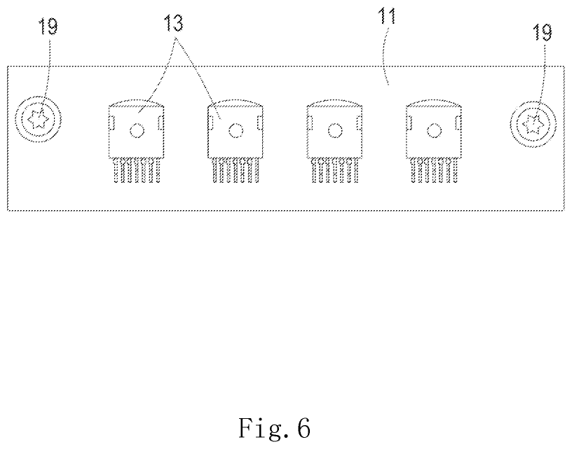

Please refer to FIG. 6 with reference to FIGS. 3-4, wherein FIG. 6 illustrates a diagram showing fastening manner of the electronic device according to one embodiment of the disclosure. As shown in FIGS. 3, 4 and 6, the electronic device of the disclosure further comprises locking members 19. Meanwhile, the circuit board 11 comprises through holes 111 corresponding to the locking members 19 and the lug bosses 142. The locking members 19 pass through the through hole 111 and are locked onto the lug bosses 142 of the heat dissipation plate 14.

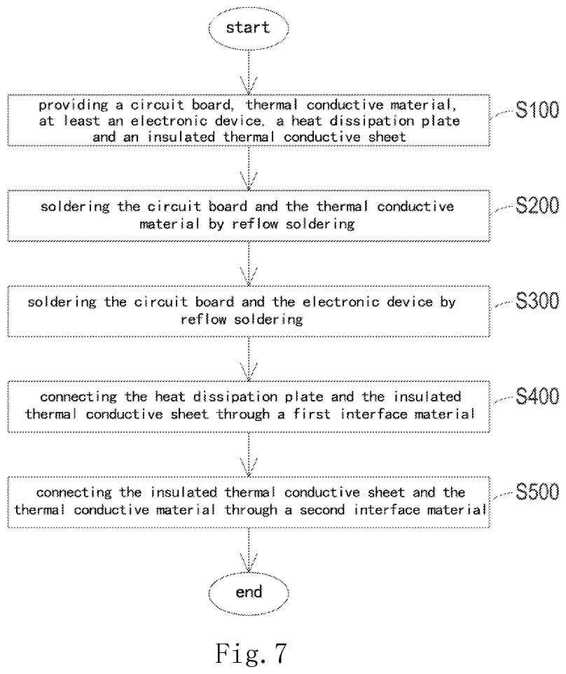

Please refer to FIG. 7 with reference to FIG. 3, wherein FIG. 7 illustrates a flow chart of a method of assembling an electronic device according to one embodiment of the disclosure. As shown in FIGS. 3 and 7, according to one embodiment of the disclosure, the disclosure provides a method of assembling an electronic device comprising steps of: firstly, as shown in step S100, providing a circuit board 11, a thermal conductive material 12, at least an electronic device 13, a heat dissipation plate 14 and an insulated thermal conductive sheet 15; secondly, as shown in step S200, soldering the circuit board 11 and the thermal conductive material 12 by reflow soldering; then, as shown in step S300, soldering the circuit board 11 and the electronic device 13 by reflow soldering; next, as shown in step S400, connecting the heat dissipation plate 14 and the insulated thermal conductive sheet 15 through a first interface material 16; and then, as shown in step S500, connecting the insulated thermal conductive sheet 15 and the thermal conductive material 12 through a second interface material 17. The circuit board 11, the thermal conductive material 12, the electronic device 13, the heat dissipation plate 14 and the insulated thermal conductive sheet 15 having been explicitly described in the above embodiments, the details are not described herein. In this embodiment, it shall be particularly noted that the assembling method of the disclosure performs reflow soldering firstly on the thermal conductive material 12, then on the electronic device 13 (such as, a surface mounted device), so as to avoid ejection of internal air to deprive of thermal conductive capability. Further, the detailed procedure of reflow soldering, and detailed procedure of connection and filling through the first interface material 16 or the second interface material 17 will be explicitly described later.

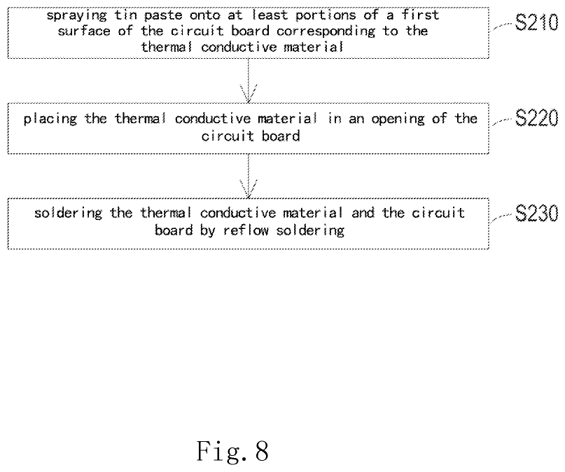

Please refer to FIG. 8 with reference to FIG. 3, wherein FIG. 8 illustrates a detailed flow chart of step S200 shown in FIG. 7. As shown in FIGS. 3 and 8, the step S200 in the method of assembling an electronic apparatus of the disclosure further comprises steps of: as shown in step S210, spraying tin paste onto at least portion of a first surface S1 or a second surface S2 of the circuit board 11 corresponding to the thermal conductive material 12 (shown by wide lines in FIG. 3); secondly, as shown in step S220, placing the thermal conductive material 12 in an opening 110 of the circuit board 11; and then, as shown in step S230, soldering the thermal conductive material 12 and the circuit board 11 by reflow soldering.

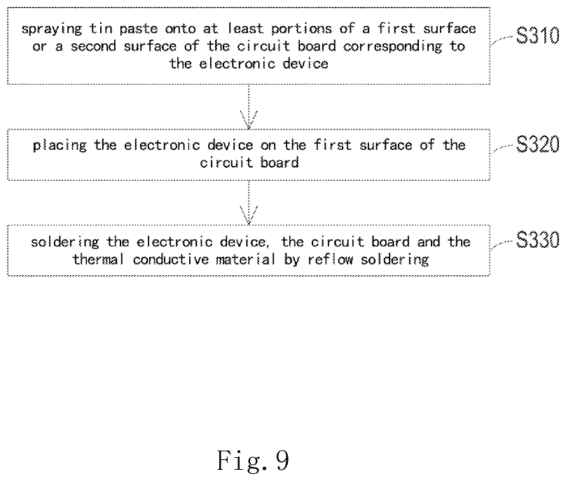

Please refer to FIG. 9 with reference to FIG. 3, where FIG. 9 illustrates a detailed flow chart of step S300 shown in FIG. 7. As shown in FIGS. 3 and 9, the step S300 in the method of assembling an electronic apparatus of the disclosure further comprises steps of: as shown in step S310, spraying tin paste onto at least portion of a first surface S1 of the circuit board 11 corresponding to the electronic device 13 (shown by wide lines in FIG. 3); secondly, as shown in step S320, placing the electronic device 13 on the first surface S1 of the circuit board 11; and then, as shown in step S330, soldering the electronic device 13, the circuit board 11 and the thermal conductive material 12 by reflow soldering.

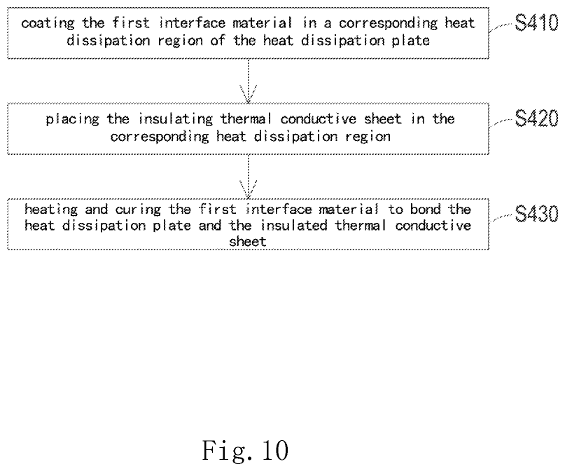

Please refer to FIG. 10 with reference to FIG. 3, where FIG. 10 illustrates a detailed flow chart of step S400 shown in FIG. 7. As shown in FIGS. 3 and 10, the step S400 in the method of assembling an electronic apparatus of the disclosure further comprises steps of: as shown in step S410, coating the first interface material 16 in a corresponding heat dissipation region of the heat dissipation plate 14; secondly, as shown in step S420, placing the insulating thermal conductive sheet 15 in the corresponding heat dissipation region; and then, as shown in step S430, heating and curing the first interface material 16 to bond the heat dissipation plate 14 and the insulated thermal conductive sheet 15.

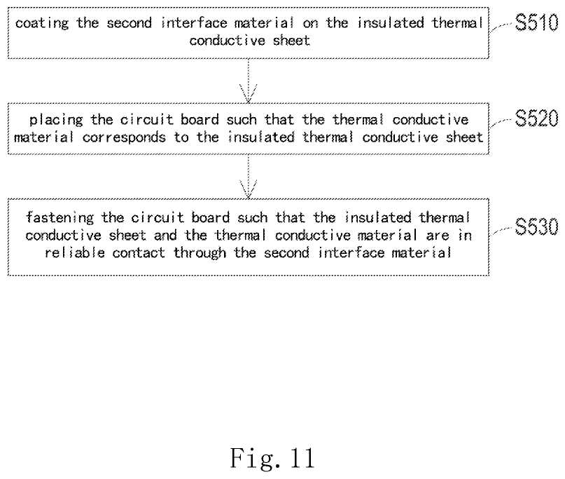

Please refer to FIG. 11 with reference to FIG. 3, where FIG. 11 illustrates a detailed flow chart of step S500 shown in FIG. 7. As shown in FIGS. 3 and 11, the step S500 in the method of assembling an electronic apparatus of the disclosure further comprises steps of: as shown in step S510, coating a second interface material 17 on the insulated thermal conductive sheet 15; secondly, as shown in step S520, placing the circuit board 11 such that the thermal conductive material 12 corresponds to the insulated thermal conductive sheet 15; and then, as shown in step S530, fastening the circuit board 11 such that the insulated thermal conductive sheet 15 and the thermal conductive material 12 are in reliable contact through the second interface material 17.

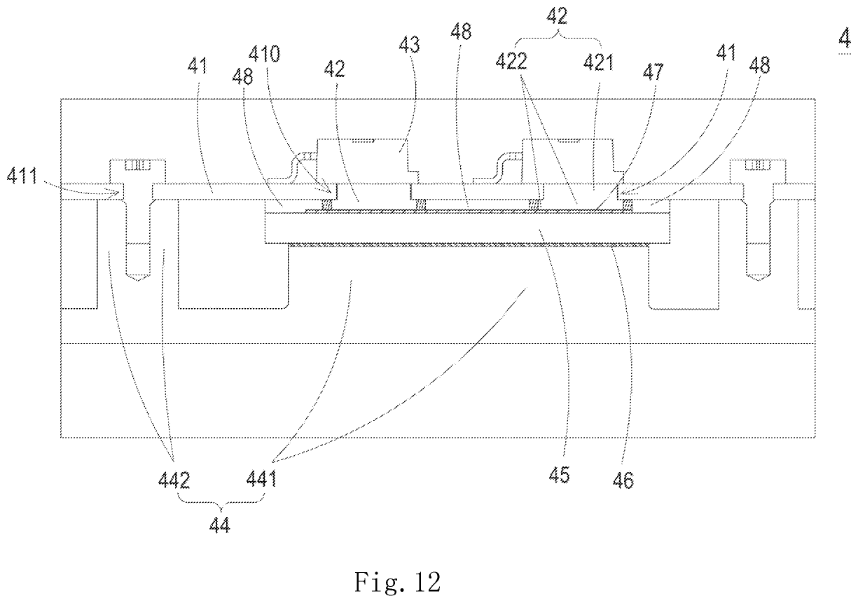

Please refer to FIG. 12, which illustrates a detailed structural diagram of an electronic apparatus according to one embodiment of the disclosure. As shown in FIG. 12, according to one embodiment of the disclosure, an electronic apparatus 4 comprises a circuit board 41, a thermal conductive material 42, at least an electronic device 43, a heat dissipation plate 44 and an insulated thermal conductive sheet 45. The circuit board 41, the thermal conductive material 42, the electronic device 43, the heat dissipation plate 44 and the insulated thermal conductive sheet 45 are similar with the circuit board 11, the thermal conductive material 12, the electronic device 13, the heat dissipation plate 14 and the insulated thermal conductive sheet 15 of the electronic apparatus 1 in the above embodiments. Meanwhile, a first interface material 46 is disposed between the insulated thermal conductive sheet 45 and the heat dissipation plate 44, and a second interface material 47 is disposed between the thermal conductive material 42 and the insulated thermal conductive sheet 45, which are also similar with those in the above embodiments, so the details are not described herein. In this embodiment, the electronic apparatus 4 further comprises at least one thermal conductive pad 48, each of which being disposed between the circuit board 41 and the insulated thermal conductive sheet 45.

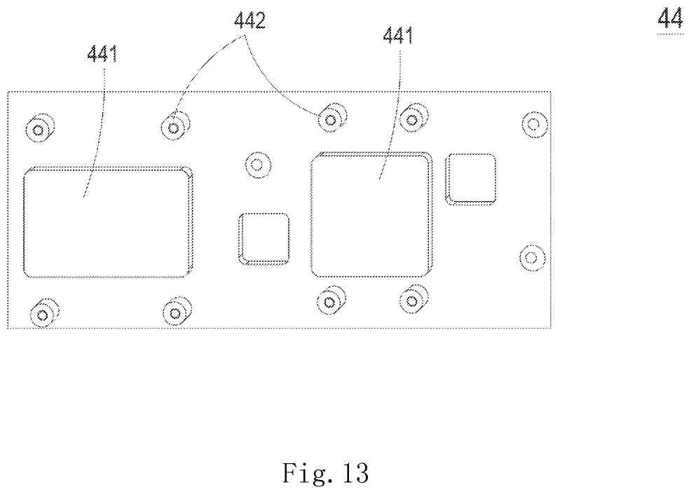

Please refer to FIG. 13 with reference to FIG. 12, wherein FIG. 13 illustrates a detailed structural diagram of a heat dissipation plate of the electronic apparatus according to one embodiment of the disclosure. As shown in FIGS. 12 and 13, the heat dissipation plate 44 of the electronic apparatus 4 of the disclosure may further comprise protruding parts 441. Milling processing is preferably applied to the protruding parts 441 to ensure their planarization and promote heat dissipation capability effectively. Moreover, the protruding parts 441 are formed at positions corresponding to the thermal conductive material 42. It is preferable that each of the protruding parts 441 corresponds to a plurality of electronic device 43 (each the protruding parts 441 shown in FIG. 13 correspond to at least four or more electronic devices 43), but the disclosure is not limited thereto.

In conclusion, the disclosure provides an electronic apparatus and a method of assembling an electronic apparatus, which can effectively reduce product volume and simplify a flow channel by a thermal conductive insulated material disposed between a thermal conductive material and a heat dissipation plate and cooperating with the heat dissipation plate. In addition, the disclosure also has at least one of the following advantages: I. the power transistor in such packaging form has a relatively small volume, and occupies a small product space; II. there is a variety of options for the fixing form, including, for example, using an elastic clamp for fixing, or locking the circuit board directly by screws; III. the flow channel of water-cooling system has a simple design, and small flow resistance, and good heat dissipation effect can be ensured even using a plane water channel; and IV. a protruding part feature may be added onto the heat dissipation plate through a CNC process, so as to ensure reliable contact between the thermal conductive material and the heat dissipation plate on the circuit board with a small processing area, and achieve better heat dissipation performance. Although the disclosure has been described in detail in the above embodiments, those skilled in the art shall make various modifications without departing from the scope protected by the appended claims.

What is claimed is:

1. An electronic apparatus, comprising:
a circuit board having a first surface, a second surface and an opening, wherein the opening is between the first surface and the second surface;
a thermal conductive material at least partially passing through the opening and in contact with the circuit board;
at least one electronic device disposed on the first surface of the circuit board and in contact with the thermal conductive material;
a heat dissipation plate disposed on the second surface of the circuit board; and
an insulated thermal conductive sheet disposed between the thermal conductive material and the heat dissipation plate.

2. The electronic apparatus according to claim 1, wherein the thermal conductive material has a main body part passing through the opening and partially projecting out of the second surface, and an extension part extending out of the main body part towards both sides of the main body part along a direction parallel to the circuit board and in contact with the second surface of the circuit board.

3. The electronic apparatus according to claim 1, wherein the insulated thermal conductive sheet is an aluminum oxide ceramic sheet or an aluminum nitride ceramic sheet.

4. The electronic apparatus according to claim 1, further comprising a first interface material, wherein the first interface material is disposed between the insulated thermal conductive sheet and the heat dissipation plate and is a liquid bond.

5. The electronic apparatus according to claim 4, further comprising a second interface material, wherein the second interface material is disposed between the thermal conductive material and the insulated thermal conductive sheet and is a thermally conductive silicone grease.

6. The electronic apparatus according to claim 1, wherein the heat dissipation plate further comprises a protruding part formed at a position corresponding to the thermal conductive material.

7. The electronic apparatus according to claim 6, wherein an area of a top surface of the protruding part is twice of an area of a bottom surface of the electronic device.

8. The electronic apparatus according to claim 6, wherein the protruding part has a height larger than or equal to 0.5 mm.

9. The electronic apparatus according to claim 6, wherein the protruding part corresponds to one or more electronic devices.

10. The electronic apparatus according to claim 1, further comprising at least one thermal conductive pad, wherein each of the thermal conductive pads is disposed between the circuit board and the insulated thermal conductive sheet.

11. The electronic apparatus according to claim 1, wherein the electronic device is an MOSFET.

12. The electronic apparatus according to claim 1, wherein the electronic device is a power transistor under Surface Mounted Technology.

13. The electronic apparatus according to claim 1, further comprising an elastic clamp with one end locked onto the circuit board and the other end pressed against the electronic device.

14. The electronic apparatus according to claim 1, further comprising a locking member, wherein the circuit board further comprises a through hole, and the locking member is locked onto the heat dissipation plate through the through hole.

15. A method of assembling an electronic apparatus, comprising steps of:
(a) providing a circuit board, a thermal conductive material, an electronic device, a heat dissipation plate and an insulated thermal conductive sheet;
(b) soldering the circuit board and the thermal conductive material by reflow soldering;
(c) soldering the circuit board and the electronic device by reflow soldering;
(d) connecting the heat dissipation plate and the insulated thermal conductive sheet with a first interface material; and
(e) connecting the insulated thermal conductive sheet and the thermal conductive material with a second interface material.

16. The method of assembling an electronic apparatus according to claim 15, wherein the step (b) further comprises steps of:
(b1) spraying tin paste onto at least portions of a first surface of the circuit board corresponding to the thermal conductive material;
(b2) placing the thermal conductive material in an opening of the circuit board; and
(b3) soldering the thermal conductive material and the circuit board by reflow soldering.

17. The method of assembling an electronic apparatus according to claim 16, wherein the step (c) further comprises steps of:
(c1) spraying tin paste onto at least portions of a first surface or a second surface of the circuit board corresponding to the electronic device;
(c2) placing the electronic device on the first surface of the circuit board; and
(c3) soldering the electronic device, the circuit board and the thermal conductive material by reflow soldering.

18. The method of assembling an electronic apparatus according to claim 15, wherein the step (d) further comprises steps of:
(d1) coating the first interface material in a corresponding heat dissipation region of the heat dissipation plate;
(d2) placing the insulating thermal conductive sheet in the corresponding heat dissipation region; and
(d3) heating and curing the first interface material to bond the heat dissipation plate and the insulated thermal conductive sheet.

19. The method of assembling an electronic apparatus according to claim 18, wherein the step (e) further comprises steps of:
(e1) coating the second interface material on the insulated thermal conductive sheet;
(e2) placing the circuit board such that the thermal conductive material corresponds to the insulated thermal conductive sheet; and
(e3) fastening the circuit board such that the insulated thermal conductive sheet and the thermal conductive material are in reliable contact through the second interface material.

20. The method of assembling an electronic apparatus according to claim 19, wherein the first interface material is a liquid bond, the second interface material is a thermally conductive silicone grease, and the heat dissipation plate has a protruding part formed in the corresponding heat dissipation region and a top surface of the protruding part planarized through milling processing.
